(19) United States
(12) Patent Application Publication
(10) Pub. No.: US 2025/0230345 A1
(43) Pub. Date: Jul. 17, 2025

(54) COMPOSITION FOR CHEMICAL-MECHANICAL POLISHING AND METHOD FOR USING COMPOSITION

(71) Applicant: FUJIMI INCORPORATED, Aichi (JP)

(72) Inventor: Shogo ONISHI, Aichi (JP)

(21) Appl. No.: 18/853,936

(22) PCT Filed: Mar. 22, 2023
(86) PCT No.: PCT/JP2023/011114

§ 371 Date: Oct. 3, 2024

Related U.S. Application Data
(60) Provisional application No. 63/328,864, filed on Apr. 8, 2022.

(51) Int. Cl. C09K 3/14; H01L 21/306

(52) U.S. Cl. CPC C09K 3/1463; C09K 3/1409; H01L 21/30625

(57) ABSTRACT

The present disclosure relates to chemical mechanical polishing (CMP) compositions for polishing molybdenum surfaces.

In particular, the CMP composition includes abrasive grains, a molybdenum (Mo) removal rate enhancer, a TEOS removal rate enhancer, an oxidizer, and water, combined in specified amounts to provide a composition with advantageous properties such as high Mo and TEOS removal rates while maintaining high Mo (RR) removal rate:Mo (ER) etching rate selectivity.

The present application is based on the U.S. Provisional Patent Application for Patent No. 63/328,864, filed on Apr. 8, 2022, and the content of the disclosure is incorporated herein by reference in its entirety.

### TECHNICAL FIELD

The present disclosure relates to chemical mechanical polishing (CMP) compositions for polishing molybdenum surfaces.

### BACKGROUND ART

CMP is a process in which material is removed from a surface of a substrate (such as a semiconductor wafer) and the surface is polished (planarized) by coupling a physical process, such as abrasion, with a chemical process, such as dissolution, oxidation or chelation. In its most rudimentary form, CMP involves applying a slurry to the surface of the substrate or a polishing pad that polishes the substrate. This process achieves both the removal of unwanted material and planarization of the surface of the substrate. It is not desirable for the removal or polishing process to be purely physical or purely chemical, but rather comprise a synergistic combination of both.

CMP is used on a large variety of objects, examples of which include silicon dioxide (SiO₂) in inter-layer or buried dielectrics; metals such as aluminum (Al), copper (Cu), and tungsten (W) in wiring layers or plugs connecting to such a wiring layer; a barrier metal layer such as tantalum (Ta), tantalum nitride (TaN), and titanium (Ti); polysilicon for use as a trench capacitor; and molybdenum, which is used in a wide range of applications.

Molybdenum may be used in a variety of industrial applications, including microelectronic devices such as connectors, photo masks, and semiconductor device manufacture. In such applications, molybdenum is often initially utilized in an excess amount. This requires that some molybdenum must be removed in order to provide a substrate with suitable surface properties.

Over the years, the demand for electronic components including innovative materials such as the ones mentioned above has keeps increasing. The industry is constantly better materials. Thus, the need to develop and/or improve polishing methods and compositions to polish materials has been continuous as well. Typically, such polishing methods and/or compositions are developed according to various criteria depending on the materials or combination of materials, i.e., polishing selectivity, polishing speed, removal rate, etc.

The polishing composition described herein have uses such as, but not limited to, the CMP of molybdenum-containing substrates, which also contain TEOS (which refers to silicon dioxide produced from tetraethyl orthosilicate as a raw material).

### CITATION LIST

### Patent Literature

### Patent Literature 1

Japanese Patent Laid-Open No. 2019-071413

### Non Patent Literature

### Non Patent Literature 1

Analytical Chemistry, vol. 28, No. 12, 1956, 1982-1983 (G. W. Sears)

### Non Patent Literature 2

“Sulfonic acid-functionalized silica through quantitative oxidation of thiol groups” Chem. Commun. 246-247 (2003)

### Non Patent Literature 3

“Novel Silane Coupling Agents Containing a Photolabile 2-Nitrobenzyl Ester for Introduction of a Carboxy Group on the Surface of Silica Gel” Chemistry Letters, 3, 228-229 (2000)

### SUMMARY OF INVENTION

In accordance with the purpose(s) of the currently disclosed subject matter or problems to be solved by the invention, as embodied and broadly described herein, it is an object of the present invention to provide a composition for polishing substrates, such as those containing molybdenum, that facilitate improvement in polishing speeds when using CMP. Another object of the present invention is to provide a method for the removal of a material from a substrate, such as molybdenum and TEOS, while maintaining a low molybdenum etching rate (hereinafter, an etching rate is also described as an “ER”.)

Accordingly, the presently disclosed subject matter in one aspect relates to a polishing composition comprising abrasive grains, a molybdenum (Mo) removal rate (hereinafter, a removal rate is also described as a “RR”) enhancer, a TEOS removal rate enhancer, an oxidizer, and water, wherein the abrasive grains are a sulfonic acid-modified colloidal silica; the molybdenum removal rate enhancer is a basic amino acid; the oxidizer is a peroxide; and wherein the polishing composition has a pH of less than about 6.

In another aspect, the subject matter described herein is directed to a method for polishing a substrate, the method comprising the steps of: 1) providing the polishing composition as disclosed herein; 2) providing a substrate, wherein the substrate comprises a molybdenum-containing layer; and 3) polishing the substrate with the polishing composition to provide a polished substrate.

The present disclosure can include the following aspects and modes.

1. A polishing composition comprising abrasive grains, a molybdenum removal rate enhancer, a TEOS removal rate enhancer, an oxidizer, and water, wherein
the abrasive grains are a sulfonic acid-modified colloidal silica;
the molybdenum removal rate enhancer is a basic amino acid;
the oxidizer is a peroxide; and
   wherein the polishing composition has a pH of less than 6.

2. The polishing composition of item 1, wherein the basic amino acid is selected from the group consisting of arginine, lysine, histidine, and a combination or polymer material thereof.

3. The polishing composition of item 1 or 2, wherein the basic amino acid is arginine.

4. The polishing composition of any one of items 1 to 3, wherein the basic amino acid is present in a concentration ranging from more than 0.01 wt % and less than 1.0 wt %.

5. The polishing composition of any one of items 1 to 4, wherein the TEOS removal rate enhancer comprises an ammonium salt.

6. The polishing composition of any one of items 1 to 5, wherein the TEOS removal rate enhancer is selected from the group consisting of ammonium sulfate, ammonium nitrate, ammonium acetate, ammonium citrate and a combination thereof.

7. The polishing composition of any one of items 1 to 6, wherein the TEOS removal rate enhancer is present in a concentration ranging from about 0.05 wt % to about 1.0 wt %.

8. The polishing composition of any one of items 1 to 7, wherein the pH of the polishing composition ranges from about 2-5.

9. The polishing composition of any one of items 1 to 8, wherein the pH of the polishing composition is about 3.0 or less.

10. The polishing composition of any one of items 1 to 9, wherein the basic amino acid has a PI of at least 7.5.

11. The polishing composition of any one of items 1 to 10, wherein the basic amino acid is a natural amino acid.

12. The polishing composition of any one of items 1 to 11, wherein the abrasive grains have a mean particle size ranging from about 15 nm to about 80 nm.

13. The polishing composition of any one of items 1 to 12, wherein the abrasive grains have an average silanol group density ranging from about 1 unit/nm² to about 6.5 units/nm².

14. The polishing composition of any one of items 1 to 13, wherein the abrasive grains have an average silanol group density ranging from about 4 units/nm² to about 6 units/nm².

15. The polishing composition of any one of items 1 to 14, wherein the abrasive grains are present in a concentration ranging from about 0.5 wt % to about 5 wt %.

16. The polishing composition of any one of items 1 to 15, wherein the oxidizer is periodic acid or hydrogen peroxide.

17. The polishing composition of any one of items 1 to 16, wherein the oxidizer is present in a concentration ranging from about 0.01 wt. % to about 1.5 wt. %.

18. The polishing composition of any one of items 1 to 17, further comprising a pH-adjusting agent.

19. The polishing composition of item 18, wherein the pH-adjusting agent is an acid.

20. The polishing composition of item 18 or 19, wherein the pH-adjusting agent is selected from the group consisting of HEDP, nitric acid, sulfonic acid, acetic acid, phosphoric acid, phosphonic acid, and 2-hydroxyisobutyric acid.

21. A polishing composition comprising abrasive grains, a molybdenum removal rate enhancer, a TEOS removal rate enhancer, an oxidizer, and water, wherein
the abrasive grains are a sulfonic acid modified colloidal silica with a mean particle size ranging from about 15 to about 80 nm and an average silanol group density on the silica surface is from about 4.0 units/nm² to about 6.0 units/nm² present in a concentration of from about 0.5 wt % to about 5.0 wt %;
the molybdenum removal rate enhancer is a basic amino acid selected from the group consisting of arginine, histidine, and lysine present in a concentration of from about 0.1 wt % to about 0.5 wt %;
the TEOS removal rate enhancer is an ammonium salt selected from the group consisting of ammonium sulfate, ammonium nitrate, ammonium acetate and ammonium citrate present in a concentration of from about 0.1 wt % to about 0.5 wt %; and
the oxidizer is a peroxide present in a concentration of from about 0.1 wt % to about 1.5 wt %;
wherein the polishing composition has a pH from about 2.0 to about 5.0.

22. The polishing composition of item 21, wherein the basic amino acid is arginine.

23. The polishing composition of item 22, wherein the TEOS removal rate enhancer is ammonium sulfate.

24. The polishing composition of item 23, wherein the pH-adjusting agent is phosphoric acid.

25. A polishing composition comprising abrasive grains, a molybdenum removal rate enhancer, a TEOS removal rate enhancer, an oxidizer, and water, wherein a ratio of molybdenum removal rate (A/minute) to molybdenum etching rate (Å/minute) is at least 50.

26. A method for polishing a substrate, the method comprising the steps of:
(a) providing the polishing composition of any one of the preceding items;
(b) providing a substrate, wherein the substrate comprises a molybdenum-containing layer;
   and
(c) polishing the substrate with the polishing composition to provide a polished substrate.

27. The method of item 26, wherein the method has a ratio of molybdenum removal rate to molybdenum etching rate of at least about 50.

28. The method of item 26 or 27, wherein the substrate further comprises a TEOS layer.

29. The method of item 28, wherein the molybdenum (Mo) removal rate is greater than the TEOS removal rate.

30. The method of item 29, wherein the substrate is a semiconductor.

The present invention can be understood more readily by reference to the following detailed description of the invention and the examples included therein.

Before the present compounds, compositions, articles, systems, devices, and/or methods are disclosed and described, it is to be understood that they are not limited to specific synthetic methods unless otherwise specified, or to particular components unless otherwise specified, as such may, of course, vary. It is also to be understood that the terminology used herein is for describing particular aspects only, and is not intended to be limiting. Although, any methods and materials that are similar or equivalent to those described herein can be used in the practice or testing of the present invention, example methods and materials are now described. If a characteristic or an aspect of the present disclosure is described from the viewpoint of a Markush group, those skilled in the art will recognize that the present disclosure is described from the viewpoint of any individual constituent of the Markush group or a partial group of the constituents of the Markush group thereby. Two or more types of each component constituting a polishing composition may be contained in the polishing composition in combination unless otherwise specified, and, in the case of the combination of the two or more types thereof, the descriptions of the used amount and the added amount thereof can mean the total amounts thereof.

Described herein are compositions comprising abrasive grains, a molybdenum removal rate enhancer, an oxidizer, and water. In some embodiments, these polishing compositions may further comprise a TEOS removal rate enhancer and/or a pH-adjusting agent. These polishing compositions are intended for polishing a substrate where the polishing compositions exhibit at least one benefit such as: 1) a low molybdenum etching rate (ER); 2) a high molybdenum removal rate (RR); 3) a high TEOS removal rate; 4) high Mo (RR):Mo (ER) ratio; and 5) high composition stability. The Mo (RR):Mo (ER) ratio is a ratio of the molybdenum removal rate [Å/minute] to the molybdenum etching rate [Å/minute].

The molybdenum etching rate, molybdenum removal rate, TEOS removal rate, and high Mo (RR):Mo (ER) ratio of the polishing compositions described herein are key properties. Compositions exhibiting these key properties may be obtained by use of specific components in requisite amounts. For example, in an embodiment, a polishing composition comprising abrasive grains, a molybdenum removal rate enhancer, a TEOS removal rate enhancer, an oxidizer, and water has been found to provide a high Mo and TEOS removal rates and low molybdenum etching rate, wherein the concentrations of each component of the polishing composition must be present in specific amounts.

The polishing compositions described herein have uses such as, but not limited to, the CMP of molybdenum-containing substrates.

### A. Definitions

Listed below are definitions of various terms used to describe this invention. These definitions apply to the terms as they are used throughout this specification, unless otherwise limited in specific instances, either individually or as part of a larger group.

As used in the specification and the appended claims, the singular forms “a,” “an” and “the” include plural referents unless the context clearly dictates otherwise. Thus, for example, reference to “abrasive grains” or “a pH-adjusting agent” includes mixtures of two or more types of such abrasive grains or pH-adjusting agents.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It will also be understood that there are a number of values disclosed herein, and that each value is herein disclosed as “about” that particular value in addition to the value itself. For example, if the value “10” is disclosed, then “about 10” is also disclosed. It will also be understood that each unit between two particular units is also disclosed. For example, if 10 and 15 are disclosed, then 11, 12, 13, and 14 are also disclosed. The “about XX” used herein can be XX±10%, and the “XX” as used here is any number. The disclosure of “about XX” used herein shall also include the disclosure of “XX” without the term “about”.

References in the specification and concluding claims to parts by weight of a particular element or component in a composition denote the weight relationship between the element or component and any other elements or components in the composition or article for which a part by weight is expressed. Thus, in a compound containing 2 parts by weight of component “X” and 5 parts by weight of component “Y,” “X and Y” are present at a weight ratio of 2:5, and are present in such ratio regardless of whether additional components are contained in the compositions.

A weight percent (wt %) of a component, unless specifically stated to the contrary, is based on the total weight of the vehicle or composition in which the component is included.

As used herein, the terms “optional” and “optionally” mean that the subsequently described event or circumstance can or cannot occur, and that the description includes instances where said event or circumstance occurs and instances where it does not.

### B. Polishing Composition

The present disclosure especially provides a CMP composition comprising abrasive grains, a molybdenum (Mo) removal rate enhancer, a TEOS removal rate enhancer, an oxidizer, and water combined in specific amounts, wherein the composition has advantageous characteristics such as high Mo and TEOS removal rates while maintaining a low Mo etching rate.

The fundamental mechanism of CMP is to soften a surface layer by chemical reaction and then remove the softened layer by mechanical force with abrasive particles (abrasive grains).

In polishing compositions for use with molybdenum (Mo) and TEOS-containing substrates, one key performance metric is a high Mo removal rate while maintaining a low Mo etching rate. Polishing compositions with high Mo (RR):Mo (ER) selectivity are ideally formulated at pH=less than about 6. These and other aspects will be discussed further herein. The TEOS as used herein means SiO₂ derived from tetraethyl orthosilicate.

In light of the complexity surrounding the various mechanisms of Mo and TEOS removal rates, it is critical to identify compositions enabling a high Mo and high TEOS removal rate, while simultaneously enabling a low Mo etching rate, and thus providing highly efficient polishing compositions.

It was surprising and unexpected to discover that the polishing compositions disclosed herein are able to achieve high molybdenum (Mo) rates and low Mo etching rates while at the same time also maintaining high TEOS removal rates. Thus, key aspects of the polishing compositions described herein include, but are not limited to: 1) high Mo removal rates (RR); 2) low Mo etching rate (ER); 3) high Mo RR/Mo ER ratio; 4) high TEOS RR; and 5) a key pH. As described herein, the combination of specific components in specified amounts is key to obtaining these desired properties.

### 1. Abrasive Grains

The polishing composition described herein contains abrasive grains. The abrasive grains are typically metal oxide abrasive grains preferably selected from the group consisting of silica, alumina, titania, zirconia, germania, ceria and mixtures thereof. In some embodiments, the abrasive grains are silica. In a further embodiment, the abrasive grains are colloidal silica.

In some embodiments, the abrasive grains are either a commercial product or a synthetic product. As a method for producing colloidal silica, for example, a sodium silicate method and a sol-gel method can be exemplified, and colloidal silica produced by either method can be used preferably as the abrasive grains of the present invention. However, in the light of reducing metal impurities, colloidal silica produced by the sol-gel method, which can produce colloidal silica at high purity, is more preferable.

The abrasive grains can have any suitable particle size. In some embodiments, the abrasive grains used in the present invention have an average primary particle size of 10 nm or more and 100 nm or less. In some embodiments, the abrasive grains used in the present invention have an average primary particle size of from about 10 nm to about 100 nm, from about 10 nm to about 80 nm, from about 10 nm to about 75 nm, from about 15 nm to about 70 nm, from about 20 to about 65 nm, from about 25 to about 60 nm, from about 30 to about 55 nm, from about 30 to about 50 nm, from about 30 to about 40 nm, or from about 32 nm to about 38 nm. In some embodiments, the abrasive grains used in the present invention have an average primary particle size of from about 15 nm to about 80 nm, from about 20 nm to about 75 nm, from about 35 nm to about 70 nm, or from about 35 nm to about 60 nm.

A lower limit of the average primary particle size of the abrasive grains is preferably 12 nm or more, 23 nm or more, 25 nm or more, 30 nm or more, or 35 nm or more. Further, an upper limit of the average primary particle size of the abrasive grains is preferably less than 90 nm, less than 80 nm, less than 75 nm, less than 60 nm, less than 50 nm, less than 40 nm or less than 35 nm or less. An upper limit of the average primary particle size of the abrasive grains is preferably 90 nm or less, 80 nm or less, 75 nm or less, 60 nm or less, 50 nm or less, 40 nm or less, or 35 nm or less.

In some embodiments, the average primary particle sizes of the abrasive grains are measured by an FE-SEM (field emission scanning electron microscope). In some embodiments, the average primary particle size of the abrasive grains can be calculated from the specific surface area of the abrasive grains measured by the BET method with “Flow SorbII 2300”, which is manufactured by Micromeritics Instrument Corporation, and the density of the abrasive grains. In Examples, a device manufactured by Micromeritics Instrument Corporation is used.

The abrasive grains can have any suitable mean particle size. For example, the abrasive grains can have a mean particle size of from about 10 nm to about 150 nm, from about 20 nm to about 120 nm, from about 30 nm to about 100 nm, from about 40 nm to about 90 nm, from about 50 nm to about 80 nm, from about 55 nm to about 75 nm, or from about 60 nm to about 70 nm. In some embodiments, the abrasive grains can have a mean particle size of from about 5 nm to about 100 nm, from about 10 nm to about 80 nm, from about 15 nm to about 60 nm, from about 20 to about 40, from about 25 nm to about 35 nm. Bigger size effects high removal rate, smaller size getting more smooth surface after polishing.

In some embodiments, the abrasive grains can have a mean particle size of about 10 nm or more, about 25 nm or more, about 30 nm or more, about 50 or more, or about 60 nm or more. Alternatively, or in addition, the abrasive grains can have a mean particle size of about 150 nm or less, about 120 nm or less, about 100 nm or less, about 75 nm or less, about 50 nm or less, about 40 nm or less, or about 30 nm or less. In some embodiments, the abrasive grains can have a mean particle size of 10 nm or more, 15 nm or more, 20 nm or more, 25 nm or more, 30 nm or more, 35 nm or more, 40 nm or more, 45 nm or more, 50 nm or more, 55 nm or more, 60 nm or more, or 65 nm or more. The mean particle size of the abrasive grains can be measured by laser diffraction using a particle size analyzer (Horiba Particle Size Distribution tool). In some embodiments, the average secondary particle size of the abrasive grains can be calculated by dynamic light scattering using a “UPA-UT151”, which is manufactured by MicrotracBEL Corp. In Examples, a device manufactured by MicrotracBEL Corp. is used.

In some embodiments, the degree of association (mean particle size/average primary particle size) of the abrasive grains is 1.2 or more, 1.4 or more, 1.6 or more, 1.8 or more, 1.9 or more, 2.0 or more, 2.1 or more, or 2.2 or more. In some embodiments, the degree of association (mean particle size/average primary particle size) of the abrasive grains is 4.0 or less, 3.5 or less, 3.2 or less, 3.0 or less, 2.8 or less, 2.6 or less, 2.4 or less, 2.2 or less, or 2.1 or less.

The abrasive grains can have any suitable surface area. For example, the abrasive grains can have an average BET surface area (BET specific surface area) of about 45 m²/g or more, about 40 m²/g or more, about 45 m²/g or more, about 50 m²/g or more, about 55 m²/g or more, about 60 m²/g or more, about 65 m²/g or more, or about 70 m²/g or more.

Alternatively, or in addition, the abrasive grains can have an average BET surface area (BET specific surface area) of about 400 m²/g or less, about 350 m²/g or less, about 300 m²/g or less, about 280 m²/g or less, about 260 m²/g or less, about 240 m²/g or less, about 220 m²/g or less, about 200 m²/g or less, 180 m²/g or less, 160 m²/g or less, about 140 m²/g or less, about 120 m²/g or less, or about 100 m²/g or less.

In some embodiments, the abrasive grains can have an average BET surface area (BET specific surface area) in a range from about 30 m²/g to about 150 m²/g, from about 40 m²/g to about 140 m²/g, from about 50 m²/g about 130 m²/g, from about 60 m²/g to about 120 m²/g, from about 65 m²/g to about 110 m²/g, or from about 70 m²/g to about 100 m²/g.

In some embodiments, the abrasive can have an average surface area (BET specific surface area) in an range from about 100 m²/g to about 400 m²/g, from about 120 m²/g to about 350 m²/g, from about 140 m²/g to about 300 m²/g, from about 160 m²/g to about 290 m²/g, from about 180 m²/g to about 280 m²/g.

The average silanol group density on the silica surface of the abrasive grains can vary. In some embodiments, the average silanol group density on the silica surface of the abrasive grains contained in the polishing composition of the present invention is 6.0 units nm² or less. If the average silanol group density is more than 6.0 units nm⁻², hardness of the abrasive grains is low, and the polishing speed is accordingly lowered.

The average silanol group density on the silica surface of the abrasive grains is preferably 5.9 units nm² or less, is more preferably 5.3 units nm² or less, is more preferably 4.5 units nm⁻² or less, and is further preferably 3.5 units nm⁻² or less.

In some embodiments, the average silanol group density on the surface of the abrasive grains is from about 1 unit nm⁻² to about 6 units nm⁻², from about 2 units nm⁻² to about 6.0 units nm⁻², from about 3 units nm⁻² to about 6 units nm⁻², from about 4 units nm⁻² to about 6 units nm⁻², or from about 5 units nm² to about 6 units nm². In some embodiments, the average silanol group density on the surface of the abrasive grains is from about 4 units nm⁻² to about 6 units nm⁻². In some embodiments, the average silanol group density on the surface of the abrasive grains is more than 4.5 units nm⁻², 4.6 units nm⁻² or more, 4.7 units nm⁻² or more, 4.8 units nm² or more, 4.9 units nm⁻² or more, 5.0 units nm⁻² or more, 5.1 units nm⁻² or more, or 5.2 units nm⁻² or more.

Incidentally, a lower limit of the average silanol group density is generally 0.

The average silanol group density per unit surface area of the abrasive grains can be calculated by the Sears method using neutralization titration described in Analytical Chemistry, vol. 28, No. 12, 1956, 1982 to 1983 by G. W. Sears. The calculation formula for the average silanol group density is calculated by the following equation.

$$ρ = ( c \times a \times {N}_{A} ) / ( C \times S )$$

ρ: Number of silanol groups [count/nm²]
c: Concentration of sodium hydrate solution used in titration [mol/L]
a: Volume of sodium hydroxide solution required for increasing pH from 4.0 to 9.0 (L)
N_{A}: Avogadro's number (6.022×10²³ [count/mol])
C: Mass of silica [g]
S: BET specific surface area [nm²/g]

The number of silanol groups per unit surface area of the abrasive grains can be controlled by selection of the method for producing abrasive grains, or the like.

Moreover, the abrasive grains may be surface-modified as long as their average silanol group density is within the above-described range. In particular, colloidal silica with organic acid immobilized thereto is preferable. Such immobilization of the organic acid to surfaces of the colloidal silica contained in the polishing composition is made by, for example, chemically bonding functional groups of the organic acid with the surfaces of the colloidal silica. The organic acid is not immobilized to the colloidal silica just by allowing the colloidal silica and the organic acid to coexist. If immobilizing sulfonic acid that is a kind of such organic acid to the colloidal silica, for example, a method described in “Sulfonic acid-functionalized silica through quantitative oxidation of thiol groups”, Chem. Commun. 246-247 (2003) can be adopted. More specifically, by coupling a silane coupling agent having thiol groups such as 3-mercaptopropyltrimethoxysilane with the colloidal silica, and subsequently oxidizing the thiol groups with hydrogen peroxide, the colloidal silica with the sulfonic acid immobilized to its surface can be obtained. Alternatively, if immobilizing carboxylic acid to the colloidal silica, for example, a method described in “Novel Silane Coupling Agents Containing a Photolabile 2-Nitrobenzyl Ester for Introduction of a Carboxy Group on the Surface of Silica Gel”, Chemistry Letters, 3, 228-229 (2000)” can be adopted. More specifically, by coupling a silane coupling agent containing photolabile 2-nitrobenzyl ester with the colloidal silica and subsequently irradiating the colloidal silica with light, the colloidal silica with carboxylic acid immobilized to its surface can be obtained.

Incidentally, the abrasive grains used in some of the present Working examples and/or Comparative Examples are sulfonic acid surface-modified.

The amount of the abrasive grains present in the disclosed polishing composition can vary. In some embodiments, the amount of the abrasive grains in the polishing composition is about 0.01 wt % or more, about 0.05 wt % or more, about 0.1 wt % or more, about 0.2 wt % or more, about 0.25 wt % or more, about 0.5 wt % or more, about 0.75 wt % or more, about 1 wt % or more, about 2 wt % or more, about 3 wt % or more, about 4 wt % or more, or about 5 wt % or more. Alternatively, or in addition, the amount of the abrasive grains in the polishing composition can be about 5 wt % or less, about 3 wt % or less, about 2 wt % or less, about 1 wt % or less, about 0.75 wt % or less, about 0.5 wt % or less, about 0.25 wt % or less, about 0.1 wt % or less, about 0.05 wt % or less, about 0.01 wt % or less, or about 0.05 wt % or less. In some embodiments, the amount of the abrasive grains in the polishing composition can be in a range from about 0.01 wt % to about 5 wt %, about 0.5 wt % to about 5 wt %, from about 0.5 wt % to about 2.5 wt %, from about 0.5 wt % to about 2.0 wt %, from about 1.0 wt % to about 2.0 wt %, or from about 1.25 wt % to about 1.75 wt %. In some embodiments, the amount of the abrasive grains in the polishing composition is more than 0.5 wt %, more than 1.0 wt %, 1.2 wt % or more, more than 1.5 wt %, 2.0 wt % or more, 3.0 wt % or more, 4.0 wt % or more, or 4.5 wt % or more. In some embodiments, the amount of the abrasive grains is 0.1 to 6.0 wt %.

In some embodiments, the amount of abrasive grains has an effect on the properties of the polishing composition, such as Mo RR and TEOS RR. In an embodiment, the amount of the abrasive grains is from about 1.0 wt % to about 3.0 wt %, from about 1.25 wt % to about 2.25 wt %, or from about 1.25 wt % to about 2.0 wt %. In an embodiment, the amount of the abrasive grains is about 1.5 wt % with respect to the entire composition.

While the abrasive grains can be of any reasonable size, the size of the abrasive grains influences the smoothness of the finish obtained. Precision polishing operations materials such as optical components, plastics, metals, gemstones, semiconductor components, and the like typically involve the use of abrasive grains with smaller sizes. For example, compositions for use in connection with precision polishing involve suspensions of abrasive grains with smaller average particle sizes.

In an embodiment the abrasive grains are colloidal silica. In some embodiments, the abrasive grains substantially comprise colloidal silica. As used herein, “substantially comprise” means that 95 wt % or more, preferably 98 wt % or more, more preferably 99 wt % or more of the particles constituting the abrasive grains are colloidal silica, and it includes that 100 wt % of the particles are colloidal silica. In some embodiments, such colloidal silica is surface-immobilized (denaturated, modified) with sulfonic acid.

The abrasive grains are suspended in the compositions disclosed herein and are colloidally stable. The term colloid refers to the suspension of abrasive particles (abrasive grains) in the liquid carrier. Colloidal stability refers to the maintenance of the suspension over time. In some embodiments, the suspension is stable for at least 1, 2, 3, 4, 5, 6, or 7 days. In some embodiments, the suspension is stable for at least 1 week, at least 2 weeks, at least 3 weeks, or at least 4 weeks.

In the context of this invention, an abrasive grain suspension is considered colloidally stable if, when the silica is placed into a 100-mL graduated cylinder and allowed to stand without agitation for a time of two hours, the difference between the concentration of particles in the bottom 50 mL of the graduated cylinder ([B] in terms of g/mL) and the concentration of particles in the top 50 mL of the graduated cylinder ([T] in terms of g/mL) divided by the total concentration of particles in the abrasive grain composition (abrasive grain suspension) ([C] in terms of g/mL) is less than or equal to 0.5 (i.e., ([B]−[T])/[C]≤0.5). The value of ([B]−[T]/[C]) desirably is less than or equal to 0.3, and preferably is less than or equal to 0.1. In Examples, a colloquially stable composition was evaluated as “good”, and a composition that was not “good” was evaluated as “NG”.

### 2. Oxidizer

The oxidizer added to the polishing composition has an action of oxidizing the surface of the polishing object and improves the polishing speed of the polishing object by the polishing composition. In some embodiments, the oxidizer is a peroxide. Exemplary peroxides include hydrogen peroxide, sodium peroxide, barium peroxide, and salt thereof. In some embodiments, the oxidizer is hydrogen peroxide.

Additional examples of other oxidizers include, but are not limited to, ozone water, an iron (III) salt, a silver (II) salt, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid (KIO₃), metaperiodic acid (HIO₄), orthoperiodic acid (H₅IO₆), persulfuric acid, dichloroisocyanuric acid, and salts thereof. These oxidants may be used either singly or in mixture of two or more kinds thereof. In some embodiments, the oxidizer is periodic acid.

In some embodiments, the amount of oxidizer has an effect on the properties of the polishing composition, such as Mo RR and TEOS RR. The amount of oxidizer may range from about 0.1 wt % to about 10 wt %, from about 0.25 wt % to about 7.5 wt %, from about 0.5 wt % to about 5 wt %, from about 0.5 wt % to about 3 wt %, from about 0.5 wt % to about 2 wt %, from about 0.5 wt % to about 1.5 wt %, or from about 0.75 wt % to about 1.25 wt %. In some embodiments, the oxidizer may range from about 0.001 wt % to about 2 wt %, from about 0.01 wt % to about 2 wt %, from about 0.01 wt % to about 1.5 wt %, from about 0.1 wt % to about 1.5 wt %, from about 0.5 wt % to about 1.5 wt %, from about 0.75 wt % to about 1.25 wt %, or about 1.0 wt %. In some embodiments, the oxidizer is present in an amount at about 0.01 wt % or more, about 0.1 wt % or more, about 0.25 wt % or more, about 0.5 wt % or more, about 0.75 wt % or more, about 1.0 wt % or more, or about 1.25 wt % or more. Alternatively, or in addition, the amount of oxidizer is about 5.0 wt % or less, about 3.50 wt % or less, about 2.0 wt % or less, about 1.50 wt % or less, about 1.25 wt % or less, about 1.0 wt % or less, about 0.5 wt % or less, or about 0.1 wt % or less. In some embodiments, the oxidizer is at more than 0.01 wt %.

In some embodiments, hydrogen peroxide constitutes 80 wt % or more, 85 wt % or more, 90 wt % or more, 95 wt % or more, 96 wt % or more, 97 wt % or more, 98 wt % or more, or 99 wt % or more of the oxidizer contained in the polishing composition.

In some embodiments, iodic acid constitutes 80 wt % or more, 85 wt % or more, 90 wt % or more, 95 wt % or more, 96 wt % or more, 97 wt % or more, 98 wt % or more, or 99 wt % or more of the oxidizer contained in the polishing composition.

In some embodiments, periodic acid (especially orthoperiodic acid) constitutes 80 wt % or more, 85 wt % or more, 90 wt % or more, 95 wt % or more, 96 wt % or more, 97 wt % or more, 98 wt % or more, or 99 wt % or more of the oxidizer contained in the polishing composition.

In some embodiments, the oxidizer contained in the polishing composition does not comprise metal ions. In some embodiments, the oxidizer contained in the polishing composition does not comprise iron ions. In some embodiments, the oxidizer contained in the polishing composition does not comprise iron complex ions.

The percentage of the amount of the oxidizer is measured with respect to the entire composition. Further, the percentage of oxidizer is measured as a Point Of Use (POU) composition. As used herein, the term “point of use” refers to a composition that is prepared and to be used in proximity to the planarization machine that supplies planarization fluid to an individual planarization machine for use in the CMP process. That is, the term refers to a composition (the components thereof and the ratio therebetween) to be applied (supplied) to the polishing object.

### 3. Molybdenum Removal Rate Enhancer

The polishing composition described herein contains a molybdenum (Mo) removal rate enhancer. In the present application, the molybdenum removal rate enhancer also has the function of suppressing the etching of the molybdenum surface, and namely the molybdenum removal rate enhancer functions as a molybdenum etching inhibitor (see the comparison between slurries 1 to 7). Therefore, the molybdenum (Mo) removal rate enhancer can also be referred to as a molybdenum etching inhibitor, and the agent is considered to be an agent for enhancing the molybdenum removal rate and suppressing the etching thereof. In some embodiments, the molybdenum removal rate enhancer is a basic amino acid. In some embodiments, a basic amino acid constitutes 80 wt % or more, 85 wt % or more, 90 wt % or more, 95 wt % or more, 96 wt % or more, 97 wt % or more, 98 wt % or more, or 99 wt % or more of the amino acids contained in the polishing composition.

In some embodiments, the basic amino acid has an isoelectric (PI) point ranging from about 7 to about 11, from about 7.5 to about 10.8, from about 8 to about 10.8, from about 9 to about 10.8 or from about 9.75 to about 10.8, or from about 10.0 to about 10.8. In some embodiments, the PI of the basic amino acid is at least 7, 7.5, 8, 8.5, 9, 9.5, 10, or at least 10.5

In some embodiments, the basic amino acid is a natural amino acid, i.e., a L-amino acid. In some embodiments, the basic amino acid is selected from arginine, lysine and histidine. In some embodiments, the basic amino acid is selected from L-arginine, L-lysine, and L-histidine. In some embodiments, the basic amino acid is arginine. In some embodiments, the basic amino acid is an un-natural amino acid, i.e., a D-amino acid. In some embodiments, the basic amino acid is a non-protein amino acid, i.e., ornithine.

In some embodiments, the basic amino acid is a polymer material of select natural, un-natural and/or non-protein amino acids. In some embodiments, the basic amino acid is a polymer material of a basic amino acid selected from arginine, lysine and histidine. For example, in some embodiments, the basic amino acid is a polymer material of arginine, i.e., polyarginine.

The amount of the Mo removal rate enhancer present in the polishing composition can vary. In some embodiments, the Mo removal rate enhancer (for example, a basic amino acid) is present in a concentration of more than 0.01 wt %, more than 0.05 wt %, more than 0.1 wt %, more than 0.15 wt %, more than 0.2 wt %, more than 0.3 wt %, more than 0.4 wt %, more than 0.5 wt %, more than 0.75 wt %, more than 0.9 wt %, or more than 1 wt %. Alternatively, or in addition, the concentration of the Mo removal rate enhancer in the polishing composition may be less than 1.5 wt %, less than 1.25 wt %, less than 1.0 wt %, less than 0.75 wt %, less than 0.5 wt %, less than 0.5 wt %, less than 0.25 wt %, or less than 0.1 wt %. In some embodiments, the concentration of the Mo removal rate enhancer in the polishing composition can be in the range from about 0.01 wt % to about 2 wt %, from about 0.01 wt % to about 1.5 wt %, from about 0.01 wt % to about 1.0 wt %, from about 0.01 wt % to about 0.5 wt %, or from about 0.01 wt % to about 0.2 wt %. In some embodiments, the concentration of the Mo removal rate enhancer (for example, a basic amino acid) is 0.03 wt % or more, 0.07 wt % or more, 0.15 wt % or more, 0.2 wt % or more, 0.3 wt % or more, or 0.4 wt % or more.

### 4. Tetraethyl Orthosilicate (TEOS) Removal Rate Enhancer

The polishing composition described herein contains a tetraethyl orthosilicate (TEOS) removal rate enhancer. In some embodiments, the TEOS removal rate enhancer comprises an ammonium salt. In some embodiments, the TEOS removal rate enhancer is an ammonium salt. In some embodiments, the ammonium salt is selected from ammonium sulfate, ammonium nitrate, ammonium acetate, ammonium citrate and a combination thereof. In some embodiments, the ammonium salt is ammonium sulfate. In some embodiments, the TEOS removal rate enhancer comprises sulfur atoms and an ammonium salt. In some embodiments, at least one of ammonium sulfate, ammonium acetate, and ammonium nitrate constitutes 80 wt % or more, 85 wt % or more, 90 wt % or more, 95 wt % or more, 96 wt % or more, 97 wt % or more, 98 wt % or more, or 99 wt % or more of a salt of an acid contained in the polishing composition.

The amount of the TEOS removal rate enhancer present in the polishing composition can vary. In some embodiments, the TEOS removal rate enhancer (i.e., ammonium salt) is present in a concentration of more than 0.01 wt %, more than 0.05 wt %, more than 0.1 wt %, more than 0.15 wt %, more than 0.2 wt %, more than 0.3 wt %, more than 0.4 wt %, more than 0.5 wt %, more than 0.75 wt %, more than 0.9 wt %, or more than 1 wt %. Alternatively, or in addition, the concentration of the TEOS removal rate enhancer in the polishing composition can be less than 1.5 wt %, less than 1.25 wt %, less than 1 wt %, less than 0.75 wt %, less than 0.5 wt %, less than 0.25 wt %, or less than 0.1 wt %. In some embodiments, the concentration of the TEOS removal rate enhancer in the polishing composition can be in a range from about 0.01 wt % to about 2 wt %, about 0.01 wt % to about 1.5 wt %, from about 0.05 wt % to about 1.0 wt %, from about 0.05 wt % to about 0.5 wt %, or from about 0.05 wt % to about 0.2 wt %. If the concentration of the TEOS removal rate enhancer in the polishing composition is more than 0.05 wt % and especially less than 1.0 wt %, the TEOS removal rate enhancer enables maintaining high Mo (RR):Mo (ER) ratio while improving the TEOS removal rate.

5. pH-Adjusting Agent

The polishing compositions described herein may also contain a pH-adjusting agent. The pH-adjusting agent is not particularly limited. However, the pH of the polishing composition has a direct effect on the effectiveness of the polishing composition. In some embodiments, the Mo RR enhancer and the TEOS RR enhancer are not considered as the pH-adjusting agent.

In some embodiments, the pH adjusting agent is a basic compound. The basic compound may be appropriately selected from various basic compounds that have a function of raising the pH of polishing compositions in which the compounds are dissolved. For example, an inorganic basic compound such as an alkali metal hydroxide, an alkaline earth metal hydroxide, various carbonates, bicarbonates and the like may be used. Such basic compounds may be used singly or in combination of two or more types thereof.

Specific examples of the alkali metal hydroxide include potassium hydroxide, sodium hydroxide, ammonium hydroxide, and the like. Specific examples of the carbonate and bicarbonate include ammonium hydrogen carbonate, ammonium carbonate, potassium hydrogen carbonate, potassium carbonate, sodium hydrogen carbonate, sodium carbonate and the like.

In some embodiments, the pH adjusting agent is an acidic compound, i.e., acidic pH adjusting agent. The acidic agent is not particularly limited provided that the strength of the acid is sufficient to modulate the pH of the polishing composition of the present invention. In some embodiments, the acidic agent may be an inorganic acid or an organic acid. For example, and without limitation, such an inorganic acid includes hydrochloric acid, sulfonic acid, sulfuric acid, nitric acid, boric acid, carbonic acid, hypophosphorous acid, phosphorous acid, phosphonic acid, and phosphoric acid.

For example, and without limitation, such an organic acid includes formic acid, acetic acid, chloroacetic acid, propionic acid, butanoic acid, valeric acid, 2-methylbutyric acid, N-hexanoic acid, 3,3-dimethylbutanoic acid, 2-ethylbutanoic acid, 4-methylpentanoic acid, n-heptanoic acid, 2-methyl hexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citrate, citric acid, lactic acid, diglycolic acid, 2-furancarboxylic acid, 3-furancarboxylic acid, 2-tetrahydrofurancarboxylic acid, 2-hydroxyisobutyric acid (2-hydroxyisolic acid), methoxyacetic acid, methoxyphenylacetic acid, and phenoxyacetic acid. Such organic acids also include, without limitation, organic sulfonic acid, such as methanesulfonic acid, ethanesulfonic acid, and isethionic acid. And, such organic acid also include, without limitation, organic phosphonic acid, such as 1-hydroxyethylidene-1,1-diphosphonic acid (HEDP). Such an organic acid can also include, but not limited to, 2-hydroxyisobutyric acid. In some embodiments, the pH-adjusting agent includes organic acids having a phosphonic acid group (—P(O)(OH)₂) or a group of a salt thereof.

In some embodiments, the organic acid is a compound represented by C(R¹)(R²)(R³)(R⁴) or a salt thereof, R¹ to R⁴ each independently represent a hydrogen atom, a phosphonic acid group or a group of a salt thereof, a hydroxy group, or a substituted or unsubstituted linear or branched alkyl group having 1 or more and 5 or less carbon atoms. In this case, one or more of R¹ to R⁴ are each a phosphonic acid group or a group of a salt thereof, or an alkyl group substituted with a phosphonic acid group or a group of a salt thereof. In some embodiments, the alkyl group has 1 to 4, 1 to 3, or 1 or 2 carbon atoms. In some embodiments, the substituents of the substituted alkyl group each independently represent a halogen atom and a phosphonic acid group. In some embodiments, at least one of R¹ to R⁴ is a hydroxy group.

In some embodiments, the pH-adjusting agent is selected from the group consisting of HEDP, nitric acid, sulfonic acid, acetic acid, phosphoric acid, phosphonic acid, 2-hydroxyisobutyric acid, and combinations thereof. In some embodiments, the pH adjusting agent is phosphoric acid.

In some embodiments, the pH adjusting agent is a mixture of an acid and a base. In some embodiments, the acidic and basic pH adjusting agents disclosed herein are acids and bases as defined according to the Lewis acid and base concepts generally known in the art. In some embodiments, the acidic and basic pH adjusting agents disclosed herein are acids and bases as defined according to the Brønsted acid and base concepts generally known in the art.

In an alternate embodiment, the pH adjusting agent may be a buffer containing phosphates, acetates, borates, sulfonates, carboxylates, nitrates and the like. For example, in some embodiments, ammonium salts can be used as a buffer. Such ammonium salts include, but are not limited to, ammonium sulfates, ammonium acetates, and/or ammonium nitrates.

In some embodiments, the pH of the polishing composition is adjusted to the range from about 1.0 to about 6.5, from about 1.0 to about 6.0, from about 1.5 to about 5.5, from about 2.0 to about 5.0, or from about 2.5 to about 5.0. In some embodiments, the pH is less than about 6, less than about 5, less than about 4, or less than 3. Alternatively, or in addition to, the pH is more than about 0.5, more than about 1, or more than about 2. In some embodiments, the pH is about 5.5 or less, about 5.0 or less, about 4.5 or less, about 4 or less, about 3.5 or less, about 3 or less, or about 2.5 or less. In some embodiments, the pH is about 2.5. In some embodiments, the pH of the polishing composition is 2.9 or less, 2.8 or less, 2.7 or less, or 2.6 or less.

The pH-adjusting agent may be present at a specific concentration range, regardless of pH. For example, in some embodiments, the amount of pH-adjusting agent is in a range from about 0.01 wt % to about 1 wt %, from about 0.02 wt % to about 0.75%, from about 0.1 wt % to about 0.5 wt %, from about 0.15 wt. % to about 0.25 wt. %, or about 0.2 wt. %. In some embodiments, the amount of pH-adjusting agent is present in an amount of at least about 0.001 wt %, at least about 0.01 wt %, at least about 0.05 wt %, at least about 0.1 wt %, at least about 0.15 wt %, or at least about 0.2 wt %. In some embodiments, the pH-adjusting agent is present in an amount of less than about 1 wt %, less than about 0.5 wt %, less than about 0.4 wt %, less than about 0.3 wt %, less than about 0.25 wt %, or less than about 0.2 wt %. In some embodiments, the pH-adjusting agent is present in an amount that is about 0.2 wt %.

In some embodiments, the amount of the pH-adjusting agent in the polishing composition can be an amount suitable to adjust the pH of the polishing composition to a desired value.

In some embodiments, the pH of the polishing composition can be measured using VSTAR94, which is manufactured by Thermo Fisher Scientific K.K., as a measuring device with the temperature of the polishing composition adjusted to 25° C.

### 6. Water

In an embodiment, the polishing compositions disclosed herein contain a carrier, medium, or vehicle. In an embodiment, the carrier, medium, or vehicle is water. Ion exchanged water (deionized water), pure water, ultrapure water, distilled water and the like may be used as the water. In order to reduce the amount of unwanted components present in the water, the purity of water may be increased by operations such as removal of impurity ions with an ion exchange resin, removal of contaminants with a filter, and/or distillation.

In some embodiments, the water is relatively free of impurities. In some embodiments, the water contains less than about 10% w/w, about 9% w/w, about 8% w/w, about 7% w/w, about 6% w/w, about 5% w/w, about 4% w/w, about 3% w/w, about 2% w/w, about 1% w/w, about 0.9% w/w, about 0.8% w/w, about 0.7% w/w, about 0.6% w/w, about 0.5% w/w, about 0.4% w/w, about 0.3% w/w, or less than about 0.1% w/w of impurities based on the total weight of the water.

In some embodiments, the polishing composition contains water as an aqueous carrier. As the aqueous carrier, water; alcohols such as methanol, ethanol, and ethylene glycol; ketones such as acetone; mixtures thereof; and the like can be exemplified. Among these, water is preferable as an aqueous carrier. That is, according to a preferable aspect of the present invention, the aqueous carrier contains water. According to a preferable aspect of the present invention, the aqueous carrier substantially comprises water. Such a term “substantially” means that as long as a target effect of the present invention can be achieved, it is intended that an aqueous carrier other than water is contained, and more specifically, the aqueous carrier preferably consists of water at 90 mass % or more and 100 mass % or less and the aqueous carrier(s) other than water at 0 mass % or more and 10 mass % or less, and more preferably consists of water at 99 mass % or more and 100 mass % or less and the aqueous carrier(s) other than water at 0 mass % or more and 1 mass % or less. The aqueous carrier is the most preferably water.

### 7. Additional Components

In an embodiment, the polishing compositions disclosed herein may contain additional components such as chelating agents, biocides, surfactants, or co-solvents. Additionally, or alternatively, the compositions disclosed herein can include other additives as will be understood by those skilled in the art.

In an embodiment, the additional component may include a chelating agent. The term chelating agent is intended to mean any substance that in the presence of an aqueous solution chelates metals, such as copper. Non-limiting examples of chelating agents include inorganic acids, organic acids, amines, and amino acids such as glycine, alanine, citric acid, acetic acid, maleic acid, oxalic acid, malonic acid, phthalic acid, succinic acid, nitrilotriacetic acid, iminodiacetic acid, ethylenediamine, CDTA, EDTA, DTPA, TTHA EDTMP and DTPMP. In an embodiment, the Mo RR enhancer may have a chelation effect. In an embodiment, the concept of the chelating agent does not include any basic amino acid.

In an embodiment, the additional component may be a biocide. Non-limiting examples of biocides include hydrogen peroxide, quaternary ammonium compounds, and chlorine compounds. More specific examples of the quaternary ammonium compounds include, but are not limited to, methylisothiazolinone, tetramethylammonium chloride, tetraethylammonium chloride, tetrapropylammonium chloride, alkylbenzyldimethylammonium chloride, and alkylbenzyldimethylammonium hydroxide, wherein the alkyl chain ranges from 1 to about 20 carbon atoms. More specific examples of the chlorine compounds include, but are not limited to, sodium chlorite and sodium hypochlorite. Additional examples of biocides include biguanide, aldehydes, ethylene oxide, isothiazolinone, iodophor, Kordek™ MLX from DuPont (which is an aqueous composition of 2-methyl-4-isothiazolin-3-one), KATHON™ and NEOLENE™ product families that are commercially available from Dow chemicals, and the Preventol™ family from Lanxess. In an embodiment, the biocide is Kordek™ MLX. The amount of biocide used in the polishing composition may range from about 0.00005 wt % to 0.001 wt % or from about 0.0001 wt % to 0.0005 wt %. In some embodiments, the biocide is present in an amount about 0.0001 wt %, about 0.00013 wt %, or about 0.00015 wt %.

In another embodiment, the additional component may include a surfactant. The surfactants may be anionic, cationic, nonionic, or zwitterionic and may increase lubricity of the vehicle or compositions. Non-limiting examples of the surfactants are dodecyl sulfates, sodium salts or potassium salts, lauryl sulfates, secondary alkane sulfonates, alcohol ethoxylate, acetylenic diol surfactant, quaternary ammonium-based surfactants, amphoteric surfactants, such as betaines and amino acid derivatives-based surfactants, and any combination thereof. Examples of suitable commercially available surfactants include TRITON™, TERGITOL™, and the DOWFAX™ family of surfactants manufactured by Dow Chemicals. Suitable surfactants of surfactants may also include polymers comprising ethylene oxide (EO) and propylene oxide (PO) groups such as EO-PO alkyl ether, EO-PO alkyl ether acetate and EO-PO alkyl ether phosphate. An example of EO-PO polymer is TETRONIC™ 90R4 from BASF Chemicals. The amount of surfactant used in the polishing composition may range from about 0.0005 wt % to 0.15 wt %, preferably from 0.001 wt % to 0.05 wt %, and more preferably from 0.0025 wt % to 0.025 wt %. In an embodiment, the polishing composition disclosed herein contains no surfactant, or contains a surfactant at less than 0.0005 wt % if any.

In another embodiment, the additional component may include another solvent, termed a co-solvent. Non-limiting examples of co-solvents include, but are not limited to, alcohol (such as methanol or ethanol), ethyl acetate, tetrahydrofuran, alkanes, dimethylformamide, toluene, ketones (such as acetone), aldehydes, and esters. Other non-limiting examples of co-solvents include dimethyl formamide, dimethyl sulfoxide, pyridine, acetonitrile, glycols, and mixtures thereof. The co-solvent may be employed in various amounts, preferably from a lower limit of about 0.0001, 0.001, 0.01, 0.1, 0.5, 1, 5, or 10% (wt %) to an upper limit of about 0.001, 0.01, 0.1, 1, 5, 10, 15, 20, 25, or 35% (wt %).

As described herein, the polishing compositions have specific properties, which are greatly influenced by the components in the composition, both in type and amount. Thus, certain materials may need to be excluded from the composition in order to maintain the desired properties.

The polishing slurries of the invention can be prepared by any suitable technique, many of which are known to those skilled in the art. The polishing composition can be prepared in a batch or a continuous process. Generally, the polishing composition can be prepared by combining the components disclosed herein in any order. The term “component” as used herein includes individual ingredients (e.g., abrasive grains, molybdenum removal rate enhancer, oxidizer, TEOS removal rate enhancer, and the like), as well as any combination of ingredients. For example, the abrasive grains can be dispersed in water, the molybdenum removal rate enhancer, and any other additive material can be added, and mixed by any method that is capable of incorporating the components into the polishing composition. The pH can be further adjusted, if desired, at any suitable time by addition of an acid, base or a buffer, as needed.

Accordingly, the polishing compositions described herein have specific properties exemplified by their performance in Mo removal rate, Mo etching rate, or TEOS removal rate.

For the polishing compositions disclosed herein, the polishing compositions have a molybdenum (Mo) removal rate of at least ≥about 100 Å/min; at least ≥about 200 Å/min; at least ≥about 300 Å/min; at least ≥about 400 Å/min; at least ≥about 500 Å/min; at least ≥about 600 Å/min; at least ≥about 650 Å/min; at least ≥about 700 Å/min; or at least ≥about 750 Å/min. In some embodiments, the Mo removal rate is in a range from about 100 Å/min to about 950 Å/min; from about 200 Å/min to about 800 Å/min; from about 300 Å/min to about 750 Å/min; from about 350 Å/min to about 750 Å/min; from about 400 Å/min to about 700 Å/min; from about 450 Å/min to about 650 Å/min; from about 500 Å/min to about 650 Å/min; or from about 550 Å/min to about 650 Å/min. In some embodiments, the Mo removal rate in a range from about 500 Å/min to about 700 Å/min.

For the polishing compositions disclosed herein, the polishing compositions have a TEOS removal rate of at least ≥about 10 Å/min; at least ≥about 100 Å/min; at least ≥about 150 Å/min; at least ≥about 200 Å/min; at least ≥about 250 Å/min; at least ≥about 250 Å/min; at least ≥about 275 Å/min; at least ≥about 300 Å/min; at least ≥about 325 Å/min, or at least ≥about 350 Å/min. In some embodiments, the TEOS removal rate is in a range from about 10 Å/min to about 450 Å/min; from about 50 Å/min to about 450 Å/min; from about 75 Å/min to about 400 Å/min; from about 100 Å/min to about 375 Å/min; from about 150 Å/min to about 350 Å/min; from about 175 Å/min to about 325 Å/min; from about 200 Å/min to about 325 Å/min; or from about 250 Å/min to about 300 Å/min. In some embodiments, the TEOS removal rate in a range from about 100 Å/min to about 300 Å/min.

For the polishing compositions disclosed herein, the Mo removal rate is higher than the TEOS removal rate. In some embodiments, the Mo removal rate and the TEOS removal rate are both at least ≥about 100 Å/min; at least ≥about 150 Å/min; at least ≥about 200 Å/min; at least ≥about 250 Å/min; at least ≥about 250 Å/min; or at least ≥about 275 Å/min. In some embodiments, the Mo removal rate is at least ≥about 300 Å/min and the TEOS removal rate is at least ≥about 200 Å/min.

For the polishing compositions disclosed herein, the polishing compositions have a Mo etching rate (ER) of less than about 10 Å/min; less than about 9 Å/min; less than about 8 Å/min; less than about 7 Å/min; less than about 6 Å/min; less than about 5 Å/min; less than about 4 Å/min; less than about 3 Å/min; or less than about 2 Å/min. In some embodiments, the Mo etching rate is in a range from about 1 Å/min to about 10 Å/min; from about 2 Å/min to about 9 Å/min; from about 3 Å/min to about 8 Å/min; or from about 4 Å/min to about 6 Å/min. In some embodiments, the Mo etching rate is about 10 Å/min, about 9 Å/min, about 8 Å/min, about 7 Å/min, about 6 Å/min, about 5 Å/min, about 4 Å/min, about 3 Å/min, or about 2 Å/min.

For the polishing compositions disclosed herein, the polishing compositions have a Mo (RR):Mo (ER) ratio of greater than about 50, about 70, about 90, about 95, about 125, about 135, about 140, about 145, about 150, about 175, about 200, about 225, or about 145. In some embodiments, the Mo (RR):Mo (ER) ratio is in a range from about 50 to about 250, from about 70 to about 250, from about 90 to about 250, from about 100 to about 225, from about 120 to about 200, from about 125 to about 180, from about 130 to about 175, from about 140 to about 165, or from about 150 to about 160. For the polishing compositions disclosed herein, the polishing compositions have a Mo (RR):Mo (ER) ratio of 70 or more, 80 or more, 90 or more, 100 or more, 110 or more, 120 or more, 130 or more, 140 or more, 150 or more, 160 or more, 170 or more, 180 or more, 190 or more, 200 or more, 210 or more, 220 or more, or 230 or more. For the polishing compositions disclosed herein, the polishing compositions have a Mo (RR):Mo (ER) ratio of, for example, 300 or less or 250 or less.

In some embodiments, the polishing composition is designed to have a Mo (RR):Mo (ER) ratio in the above-mentioned range.

Accordingly, as described herein, in some embodiments are polishing compositions comprising abrasive grains, a molybdenum removal rate enhancer, a TEOS removal rate enhancer, an oxidizer, and water, wherein the abrasive grains are a sulfonic acid-modified colloidal silica; the molybdenum removal rate enhancer is a basic amino acid; the oxidizer is a peroxide; and wherein the polishing composition has a pH of less than about 6. As in any embodiment above, the polishing composition is provided.

As in any embodiment above, the polishing composition wherein the basic amino acid is selected from the group consisting of arginine, lysine, histidine, or a polymer material thereof.

As in any embodiment above, the polishing composition wherein the basic amino acid is arginine.

As in any embodiment above, the polishing composition wherein the basic amino acid is present in a concentration in the range of more than 0.01 wt % and less than 1.0 wt %.

As in any embodiment above, the polishing composition wherein the TEOS removal rate enhancer comprises an ammonium salt.

As in any embodiment above, the polishing composition wherein the TEOS removal rate enhancer is selected from the group consisting of ammonium sulfate, ammonium nitrate, ammonium acetate, ammonium citrate and a combination thereof

As in any embodiment above, the polishing composition wherein the TEOS removal rate enhancer is present in a concentration ranging from about 0.05 wt. % to about 1.0 wt. %.

As in any embodiment above, the polishing composition wherein the pH of the polishing composition ranges from about 2-5.

As in any embodiment above, the polishing composition wherein the pH of the polishing composition is about 3.0 or less.

As in any embodiment above, a polishing composition wherein the basic amino acid has a PI of at least 7.5.

As in any embodiment above, a polishing composition wherein the basic amino acid is a natural amino acid.

As in any embodiment above, the polishing composition, wherein the abrasive grains have a mean particle size ranging from about 15 nm to about 80 nm.

As in any embodiment above, the polishing composition, wherein the abrasive grains have an average silanol group density ranging from about 1 unit/nm² to about 6.5 units/nm².

As in any embodiment above, the polishing composition, wherein the abrasive grains have an average silanol group density ranging from about 4 units/nm² to about 6 units/nm².

As in any embodiment above, the polishing composition, wherein the abrasive grains are present at a concentration ranging from about 0.5 wt % to about 5 wt %.

As in any embodiment above, a polishing composition wherein the oxidizer is periodic acid or hydrogen peroxide.

As in any embodiment above, a polishing composition wherein the molybdenum etching inhibitor is present in a concentration from about 0.01 wt % to about 0.1 wt %.

As in any embodiment above, a polishing composition wherein the oxidizer is present in a concentration ranging from about 0.01 wt. % to about 1.5 wt. %.

As in any embodiment above, a polishing composition wherein the polishing composition further comprising a pH-adjusting agent.

As in any embodiment above, a polishing composition wherein the pH-adjusting agent is an acid.

As in any embodiment above, the polishing composition wherein the pH-adjusting agent is selected from the group consisting of HEDP, nitric acid, sulfonic acid, acetic acid, phosphoric acid, phosphonic acid, and 2-hydroxyisobutyric acid.

As in any embodiment above, a polishing composition wherein the polishing composition is stable for a period of at least one week. In an embodiment, the pH of the composition remains unchanged after a period of at least one week. In another embodiment, the electrical conductivity (EC) of the composition remains unchanged after a period of at least one week.

In some embodiments, the lower limit of the electrical conductivity of the polishing composition is about 0.001 mS/cm, about 0.01 mS/cm, about 0.1 mS/cm, about 0.25 mS/cm, about 0.5 mS/cm, about 0.75 mS/cm, or about 1.0 mS/cm. In some embodiments, the upper limit of the electrical conductivity of the polishing composition is about 20 mS/cm, about 15 mS/cm, about 12 mS/cm, about 10 mS/cm, about 8 mS/cm, about 5 mS/cm, about 3 mS/cm, about 2 mS/cm, or about 1 mS/cm. In a further embodiment, the electrical conductivity of the polishing composition is in the range from about 0.2 mS/cm to about 1.0 mS/cm. In some embodiments, the electrical conductivity of the polishing composition is from about 0.01 mS/cm to about 15 mS/cm, from about 0.01 mS/cm to about 12 mS/cm, from about 0.01 mS/cm to about 10 mS/cm, from about 0.1 mS/cm to about 10 mS/cm, from about 0.1 mS/cm to about 8 mS/cm, from about 0.5 mS/cm to about 8 mS/cm, from about 0.75 mS/cm to about 5 mS/cm, from about 1 mS/cm to about 5 mS/cm, or from about 1 mS/cm to about 3 mS/cm.

Further, in some embodiments are a polishing composition comprising abrasive grains, a molybdenum removal rate enhancer, a TEOS removal rate enhancer, an oxidizer, and water, wherein the abrasive grains are a sulfonic acid modified colloidal silica with a mean particle size ranging from about 15 to about 80 nm and an average silanol group density on the silica surface is from about 4.0 units/nm² to about 6.0 units/nm² present in a concentration of from about 0.5 wt % to about 5.0 wt %; the molybdenum removal rate enhancer is a basic amino acid selected from the group consisting of arginine, histidine, and lysine present in a concentration of from about 0.1 wt % to about 0.5 wt %; the TEOS removal rate enhancer is an ammonium salt selected from the group consisting of ammonium sulfate, ammonium nitrate, ammonium acetate and ammonium citrate present in a concentration of from about 0.1 wt % to about 0.5 wt %; and the oxidizer is a peroxide present in a concentration of from about 0.1 wt % to about 1.5 wt %; wherein the polishing composition has a pH from about 2.0 to about 5.0.

As in any embodiment above, the polishing composition wherein the basic amino acid is arginine.

As in any embodiment above, a polishing composition wherein the TEOS removal rate enhancer is ammonium sulfate.

As in any embodiment above, a polishing composition wherein the pH-adjusting agent is phosphoric acid.

### C. Methods of Using the Polishing Compositions

The polishing compositions described herein are useful for polishing any suitable substrate. In an embodiment, the substrate to be polished can be any suitable substrate, which comprises at least one layer of molybdenum. Suitable substrates include, but are not limited to, flat panel displays, integrated circuits, memory or rigid disks, metals, interlayer dielectric (ILD) devices, semiconductors, microelectromechanical systems, ferroelectrics, and magnetic heads.

The substrate can further comprise at least one other layer, e.g., an insulating layer. The insulating layer can be a metal oxide, porous metal oxide, glass, organic polymer, fluorinated organic polymer, or any other suitable high- or low-K insulating layer. The insulating layer can comprise, consist essentially of, or consist of silicon oxide, SiN, or combinations thereof. The silicon oxide layer can comprise, consist essentially of, or consist of any suitable silicon oxide, many of which are known in the art. For example, the silicon oxide layer can comprise tetraethoxysilane (TEOS), high density plasma (HDP) oxide, borophosphosilicate glass (BPSG), high aspect ratio process (HARP) oxide, spin-on dielectric (SOD) oxide, chemical vapor deposition (CVD) oxide, plasma-enhanced tetraethyl orthosilicate (PETEOS), thermal oxide, or undoped silicate glass. In addition, TEOS means a silicon dioxide film obtained from TEOS as a raw material. BPSG, PETEOS are same meaning. In a specific embodiment, the silicon oxide layer is a tetraethoxysilane (TEOS) layer. The substrate can further comprise a metal layer. In a specific embodiment, the metal layer includes molybdenum, tungsten, titanium nitride, titanium, preferably molybdenum. The substrate can further comprise a polysilicon layer.

The subject matter disclosed herein also comprises a method for polishing a substrate with the polishing compositions described herein. The method of polishing a substrate comprises the steps of: (a) providing a substrate, (b) providing a polishing composition described herein, (c) applying the polishing composition to at least a portion of the substrate, and (d) abrading at least a portion of the substrate with the polishing composition to polish the substrate.

In the method of polishing a substrate, the polishing compositions disclosed herein have a molybdenum (Mo) removal rate of at least ≥about 100 Å/min; at least ≥about 200 Å/min; at least ≥about 300 Å/min; at least ≥about 400 Å/min; at least ≥about 500 Å/min; at least ≥about 600 Å/min; at least ≥about 650 Å/min; at least ≥about 700 Å/min; or at least ≥about 750 Å/min. In some embodiments, the Mo removal rate is in a range from about 100 Å/min to about 950 Å/min; from about 200 Å/min to about 800 Å/min; from about 300 Å/min to about 750 Å/min; from about 350 Å/min to about 750 Å/min; from about 400 Å/min to about 700 Å/min; from about 450 Å/min to about 650 Å/min; from about 500 Å/min to about 650 Å/min; or from about 550 Å/min to about 650 Å/min. In some embodiments, the Mo removal rate in a range from about 500 Å/min to about 700 Å/min.

In the method of polishing a substrate, the polishing compositions disclosed herein have a TEOS removal rate of at least ≥about 10 Å/min; at least ≥about 100 Å/min; at least ≥about 150 Å/min; at least ≥about 200 Å/min; at least ≥about 250 Å/min; at least ≥about 250 Å/min; at least ≥about 275 Å/min; at least ≥about 300 Å/min; at least ≥about 325 Å/min, or at least ≥about 350 Å/min. In some embodiments, the TEOS removal rate is in a range from about 10 Å/min to about 450 Å/min; from about 50 Å/min to about 450 Å/min; from about 75 Å/min to about 400 Å/min; from about 100 Å/min to about 375 Å/min; from about 150 Å/min to about 350 Å/min; from about 175 Å/min to about 325 Å/min; from about 200 Å/min to about 325 Å/min; or from about 250 Å/min to about 300 Å/min. In some embodiments, the TEOS removal rate in a range from about 100 Å/min to about 300 Å/min.

For the polishing compositions disclosed herein, the Mo removal rate is higher than the TEOS removal rate. In some embodiments, the Mo removal rate and the TEOS removal rate are both at least ≥about 100 Å/min; at least ≥about 150 Å/min; at least ≥about 200 Å/min; at least ≥about 250 Å/min; at least ≥about 250 Å/min; or at least ≥about 275 Å/min. In some embodiments, the Mo removal rate is at least ≥about 300 Å/min and the TEOS removal rate is at least ≥about 200 Å/min.

In the method of polishing a substrate, the polishing compositions disclosed herein have a Mo etching rate (ER) of less than about 10 Å/min; less than about 9 Å/min; less than about 8 Å/min; less than about 7 Å/min; less than about 6 Å/min; less than about 5 Å/min; less than about 4 Å/min; less than about 3 Å/min; or less than about 2 Å/min. In some embodiments, the Mo etching rate is in a range from about 1 Å/min to about 10 Å/min; from about 2 Å/min to about 9 Å/min; from about 3 Å/min to about 8 Å/min; or from about 4 Å/min to about 6 Å/min. In some embodiments, the Mo etching rate is about 10 Å/min, about 9 Å/min, about 8 Å/min, about 7 Å/min, about 6 Å/min, about 5 Å/min, about 4 Å/min, about 3 Å/min, or about 2 Å/min.

In the method of polishing a substrate, the polishing compositions disclosed herein have a Mo (RR):Mo (RE) ratio of greater than about 50, about 70, about 90, about 95, about 125, about 135, about 140, about 145, about 150, about 175, about 200, about 225, or about 145. In some embodiments, the Mo (RR):Mo (RE) ratio is in a range from about 50 to about 250, from about 70 to about 250, from about 90 to about 250, from about 100 to about 225, from about 120 to about 200, from about or from about 125 to about 180, from about 130 to about 175, from about 140 to about 165, or from about 150 to about 160.

In Accordingly, as described herein, in some embodiments are methods of using the polishing compositions, where the methods comprise the steps of: a) providing the polishing composition described herein; b) providing a substrate, wherein the substrate comprises a molybdenum (Mo) containing layer; and c) polishing the substrate with the polishing composition to provide a polished substrate.

As in any embodiment above, a method wherein the substrate is a semiconductor.

As in any embodiment, wherein the substrate further comprises a TEOS layer.

As in any embodiment above, a method wherein the Mo removal rate (RR) is at least ≥about 100 Å/min.

As in any embodiment above, a method wherein the substrate further comprises a silicon oxide layer (TEOS).

As in any embodiment above, a method wherein the Mo removal rate is greater than the TEOS removal rate.

As in any embodiment above, a method wherein the method results in Mo (RR):Mo (RE) ratio of at least about 50.

### D. Examples

The following preparations and examples are given to enable those skilled in the art to more clearly understand and to practice the present invention. They should not be considered as limiting the scope of the invention, but merely as being illustrative and representative. In the following description, operations were performed under the conditions of room temperature (25° C.) and a relative humidity of 40 to 50% RH unless otherwise specified.

In one aspect, disclosed are methods of making the polishing compositions. In another aspect are disclosed methods of using the polishing compositions to polish materials.

### EXAMPLES

### Example 1: Polishing Conditions

### Materials and Tools Used:

Polishing test conditions
200 mm Polisher Westech
Platen rotation speed: 110 rpm
Head rotation speed: 103 rpm
Flow rate: 100 mL/min
Down force: 2 psi
Polishing time: 60 sec.
Pad: Medium Hard Pad (Fujibo Holdings, Inc.; H800)
Dilution factor: 1×

### (Calculation of Polishing Speed)

The thicknesses of the polishing object before and after the polishing were determined with an optical film thickness measuring device (ASET-f5x: manufactured by KLA Corporation).

### Etching Test Conditions:

Immersed in polishing compositions at 25° C. for 3 min
Mo coupon size: 1.5 in×1.5 in

### (Calculation of Etching Rate)

The etching amounts of the coupons were determined with a table-top four-probe resistivity measuring device (ResMap 273: manufactured by Creative Design Engineering).

### Example 2: Evaluation of Various Polishing Compositions

For this study several components present in the composition were investigated. The first study was directed towards the investigation of various molybdenum (Mo) removal rate enhancer types A to M (see Table 1). These Mo removal rate enhancer types contained an amine functionality and were selected from amino acids, azoles, acid-containing amines, alkyl amines and polyvinyl alcohol.

The following components were added to deionized water in the following amounts, respectively, for preparing polishing compositions (slurries) shown in the following tables 2, 4, 5, 7, and 8. The amounts of the pH-adjusting agent was suitable for adjusting the pHs to pHs described in the following tables. Table 1 is referred to for information on the molybdenum removal rate enhancers. Table 3 is referred to for information on the abrasive grains. Table 6 is referred to for information on the TEOS removal rates enhancer.
(1) Abrasive grains;
(2) pH-adjusting agent;
(3) Molybdenum (Mo) RR enhancer;
(4) TEOS RR enhancer; and
(5) Oxidizer.

The constituents (2) to (4) were added to deionized water, the abrasive grains (1) were subsequently added, and the oxidizer (5) was added thereto just before polishing.

Table 2 shows the result for this molybdenum removal rate enhancer screening study, which indicated that basic amino acids exhibit good performance with respect to removal rate and etching rate. In particular, amino acids that exhibit a bigger negative value of the gap between PI of molybdenum removal rate enhancer and slurry pH at table 1 produced the highest performance, such as arginine, lysine and histidine.

Gap between the polishing slurry pH at POU and the PI of molybdenum removal rate enhancer is calculated “slurry pH at POU”−“PI of molybdenum removal rate enhancer”. It is preferably from about −4 to about −10, from about −6 to about −9.5, from about −7 to about −9, from about −8 to −8.5.

By contrast acidic amino acid, non-polar side chain amino acids, benzotriazole (BTA), aminocarboxylic acid compounds, alkyl amine and polyvinyl alcohol did not perform as well.

TABLE 1
Molybdenum removal rate Enhancer Types

| | | | | | Difference between |
|---|---|---|---|---|---|
| Type | Chemical name | Type | | PI | pH and PI |
| A | L-Arginine | Amino acid | Basic | 10.76 | −8.26 |
| B | L-Lysine | Amino acid | Basic | 9.75 | −7.25 |
| C | L-Histidine | Amino acid | Basic | 7.59 | −5.09 |
| D | L-Aspartic acid | Amino acid | Acidic | 2.77 | −0.27 |
| E | L-Glutamic acid | Amino acid | Acidic | 3.22 | −0.72 |
| F | L-Glycine | Amino acid | — | 5.97 | −3.47 |
| G | L-Alanine | Amino acid | — | 6 | −3.5 |
| H | Benzotriazole | Azole | — | | |
| I | Ethylenediaminetetraacetic acid | COOH | Acidic | | |
| J | Triethylenetetraminehexaacetic acid | COOH | Acidic | | |
| K | Octylamine | Amine | Cationic | | |
| L | Dodecylamine | Amine | Cationic | | |
| M | Polyvinyl alcohol | Polymer | — | | |

For example, amino acids with non-polar side chains were able to enhance Mo removal rate, but did not suppress Mo etching rate. In particular, Slurry 15 and 16 could suppress Mo etching rate, but these slurries also suppress the Mo removal rate.

TABLE 2
Molybdenum Removal Rate Enhancer Skew

| | Abrasive | | | | Mo RR | | TEOS RR | | | | | | | | |
|---|---|---|---|---|---|---|---|---|---|---|---|---|---|---|---|
| | grains | | | | enhancer | | enhancer | | Oxidizer | | Removal rate | | Etching rate | | Removal/ |
| | | Conc. | | pH | | Conc. | | Conc. | | Conc. | [Å/minute] | | [Å/minute] | | etching |
| Slurry | Type | [wt %] | pH | adjuster | Type | [wt %] | Type | [wt %] | Type | [wt %] | Mo | TEOS | Mo | Stability | rate (Mo) |
| 1 | B | 1.5 | 2.5 | HEDP | A | 0.2 | A | 0.2 | H₂O₂ | 1 | 673 | 324 | 3.4 | Good | 198 |
| 2 | B | 1.5 | 2.5 | HEDP | A | 0 | A | 0.2 | H₂O₂ | 1 | 301 | 331 | 58.4 | Good | 5 |
| 3 | B | 1.5 | 2.5 | HEDP | A | 0.01 | A | 0.2 | H₂O₂ | 1 | 321 | 321 | 10.3 | Good | 31 |
| 4 | B | 1.5 | 2.5 | HEDP | A | 0.05 | A | 0.2 | H₂O₂ | 1 | 583 | 318 | 5.5 | Good | 106 |
| 5 | B | 1.5 | 2.5 | HEDP | A | 0.1 | A | 0.2 | H₂O₂ | 1 | 644 | 321 | 4.3 | Good | 150 |
| 6 | B | 1.5 | 2.5 | HEDP | A | 0.5 | A | 0.2 | H₂O₂ | 1 | 689 | 336 | 2.8 | Good | 246 |
| 7 | B | 1.5 | 2.5 | HEDP | A | 1 | A | 0.2 | H₂O₂ | 1 | 699 | 308 | 9.4 | Good | 74 |
| 8 | B | 1.5 | 2.5 | HEDP | B | 0.2 | A | 0.2 | H₂O₂ | 1 | 521 | 301 | 5.3 | Good | 98 |
| 9 | B | 1.5 | 2.5 | HEDP | C | 0.2 | A | 0.2 | H₂O₂ | 1 | 518 | 317 | 5.7 | Good | 91 |
| 10 | B | 1.5 | 2.5 | HEDP | D | 0.2 | A | 0.2 | H₂O₂ | 1 | 311 | 330 | 61.2 | Good | 5 |
| 11 | B | 1.5 | 2.5 | HEDP | E | 0.2 | A | 0.2 | H₂O₂ | 1 | 374 | 301 | 63.4 | Good | 8 |
| 12 | B | 1.5 | 2.5 | HEDP | F | 0.2 | A | 0.2 | H₂O₂ | 1 | 489 | 330 | 58.2 | Good | 8 |
| 13 | B | 1.5 | 2.5 | HEDP | G | 0.2 | A | 0.2 | H₂O₂ | 1 | 497 | 308 | 55.9 | Good | 9 |
| 14 | B | 1.5 | 2.5 | HEDP | H | 0.2 | A | 0.2 | H₂O₂ | 1 | 201 | 291 | 20.3 | Good | 10 |
| 16 | 8 | 1.5 | 2.5 | HEDP | I | 0.2 | A | 0.2 | H₂O₂ | 1 | 28 | 218 | 18.1 | Good | 2 |
| 16 | B | 1.5 | 2.5 | HEDP | J | 0.2 | A | 0.2 | H₂O₂ | 1 | 38 | 225 | 21.3 | Good | 2 |
| 17 | B | 1.5 | 2.5 | HEDP | K | 0.2 | A | 0.2 | H₂O₂ | 1 | 472 | 333 | 67.8 | NG | 7 |
| 18 | B | 1.5 | 2.5 | HEDP | L | 0.2 | A | 0.2 | H₂O₂ | 1 | 444 | 314 | 78.3 | NG | 6 |
| 19 | B | 1.5 | 2.5 | HEDP | M | 0.2 | A | 0.2 | H₂O₂ | 1 | 101 | 98 | 62.1 | Good | 2 |

In the next study various abrasive grains were investigated exhibiting various average silanol group densities, mean particle sizes, and optionally surface modified (see Table 3). The Table 4 shows the result of such an abrasive grain skew, where various abrasive grains were investigated at a concentration range of 0.5 to 5.0 wt %. The data in Table 4 shows that surface modification on the particle surface is important, because non-modified silica caused aggregation of the particles.

TABLE 3
Abrasive grain type

| | | Surface | Average primary | Mean particle | Average silanol group |
|---|---|---|---|---|---|
| Type | Material | modification | particle size [nm] | size [nm] | density [unit/nm²] |
| A | Colloidal silica | YES | 12 | 28 | 4.5 |
| B | Colloidal silica | YES | 35 | 70 | 5.3 |
| C | Colloidal silica | No | 12 | 29 | 6.1 |
| D | Colloidal silica | No | 35 | 68 | 5.9 |
| E | Colloidal silica | No | 15 | 38 | 1.5 |

Surface modification Yes: Colloidal silica that is surface-modified (immobilized) with sulfonic acid
Surface modification No: Colloidal silica that is not surface-modified

TABLE 4
Abrasive Grain Skew

| | Abrasive | | | | Mo RR | | TEOS RR | | | | | | | | |
|---|---|---|---|---|---|---|---|---|---|---|---|---|---|---|---|
| | grains | | | | enhancer | | enhancer | | | | Removal rate | | Etching rate | | Removal/ |
| | | Conc. | | pH | | Conc. | | Conc. | Oxidizer | | [Å/minute] | | [Å/minute] | | etching |
| Slurry | Type | [wt %] | pH | adjuster | Type | [wt %] | Type | [wt %] | Type | [wt %] | Mo | TEOS | Mo | Stability | rate (Mo) |
| 1 | B | 1.5 | 2.5 | HEDP | A | 0.2 | A | 0.2 | H₂O₂ | 1 | 673 | 324 | 3.4 | Good | 198 |
| 20 | A | 1.5 | 2.5 | HEDP | A | 0.2 | A | 0.2 | H₂O₂ | 1 | 489 | 79 | 3.4 | Good | 144 |
| 21 | C | 1.5 | 2.5 | HEDP | A | 0.2 | A | 0.2 | H₂O₂ | 1 | 389 | 45 | 3.2 | NG | 122 |
| 22 | D | 1.5 | 2.5 | HEDP | A | 0.2 | A | 0.2 | H₂O₂ | 1 | 582 | 288 | 3.4 | NG | 171 |
| 23 | E | 1.5 | 2.5 | HEDP | A | 0.2 | A | 0.2 | H₂O₂ | 1 | 621 | 321 | 3.3 | NG | 188 |
| 24 | B | 0.5 | 2.5 | HEDP | A | 0.2 | A | 0.2 | H₂O₂ | 1 | 332 | 188 | 3.4 | Good | 98. |
| 25 | B | 1 | 2.5 | HEDP | A | 0.2 | A | 0.2 | H₂O₂ | 1 | 521 | 244 | 3.4 | Good | 153 |
| 26 | B | 5 | 2.5 | HEDP | A | 0.2 | A | 0.2 | H₂O₂ | 1 | 789 | 456 | 3.4 | Good | 232 |
| 27 | A | 0.5 | 2.5 | HEDP | A | 0.2 | A | 0.2 | H₂O₂ | 1 | 233 | 56 | 3.4 | Good | 69 |
| 28 | A | 1 | 2.5 | HEDP | A | 0.2 | A | 0.2 | H₂O₂ | 1 | 323 | 61 | 3.4 | Good | 95 |
| 29 | A | 5 | 2.5 | HEDP | A | 0.2 | A | 0.2 | H₂O₂ | 1 | 579 | 101 | 3.4 | Good | 170 |

In the next study numerous pH adjusters were investigated. Table 5 shows the results of the study, where slurry pH and pH adjuster was studied and demonstrated that numerous pH adjusters can be used in these polishing compositions. Regarding the slurry pH, it was observed that a pH range of 2.5 to 5.0 is optimal, as slurries with a pH 6 or more cannot achieve a high Mo removal rate and low Mo etching rate simultaneously.

TABLE 5
pH Adjuster/pH skew

| | Abrasive | | | | Mo RR | | TEOS RR | | | | | | | | |
|---|---|---|---|---|---|---|---|---|---|---|---|---|---|---|---|
| | grains | | | | enhancer | | enhancer | | | | Removal rate | | Etching rate | | Removal/ |
| | | Conc. | | pH | | Conc. | | Conc. | Oxidizer | | [Å/minute] | | [Å/minute] | | etching |
| Slurry | Type | [wt %] | pH | adjuster | Type | [wt %] | Type | [wt %] | Type | [wt %] | Mo | TEOS | Mo | Stability | rate (Mo) |
| 1 | B | 1.5 | 2.5 | HEDP | A | 0.2 | A | 0.2 | H₂O₂ | 1 | 673 | 324 | 3.4 | Good | 198 |
| 30 | B | 1.5 | 2.5 | Nitric acid | A | 0.2 | A | 0.2 | H₂O₂ | 1 | 584 | 301 | 4.1 | Good | 142 |
| 31 | B | 1.5 | 2.5 | Sulfonic acid | A | 0.2 | A | 0.2 | H₂O₂ | 1 | 521 | 298 | 4.6 | Good | 113 |
| 32 | B | 1.5 | 2.5 | Acetic acid | A | 0.2 | A | 0.2 | H₂O₂ | 1 | 633 | 333 | 3.8 | Good | 167 |
| 33 | B | 1.5 | 2.5 | Phosphoric | A | 0.2 | A | 0.2 | H₂O₂ | 1 | 598 | 302 | 3.7 | Good | 162 |
| | | | | acid | | | | | | | | | | | |
| 34 | B | 1.5 | 2.5 | 2-Hydroxy- | A | 0.2 | A | 0.2 | H₂O₂ | 1 | 524 | 341 | 3.3 | Good | 159 |
| | | | | isobutyric | | | | | | | | | | | |
| | | | | acid | | | | | | | | | | | |
| 35 | B | 1.5 | 3 | HEDP | A | 0.2 | A | 0.2 | H₂O₂ | 1 | 554 | 312 | 3.8 | Good | 146 |
| 36 | B | 1.5 | 4 | HEDP | A | 0.2 | A | 0:2 | H₂O₂ | 1 | 483 | 288 | 4.1 | Good | 118 |
| 37 | B | 1.5 | 5 | HEDP | A | 0.2 | A | 0.2 | H₂O₂ | 1 | 441 | 245 | 4.4 | Good | 100 |
| 38 | B | 1.5 | 6 | HEDP | A | 0.2 | A | 0.2 | H₂O₂ | 1 | 238 | 122 | 10.7 | Good | 22 |

TABLE 6
TEOS RR Enhancer

| Type | Chemical name |
|---|---|
| A | Ammonium sulfate |
| B | Ammonium acetate |
| C | Ammonium nitrate |

Table 7 shows the results of this study, which indicated that 0.05-1.0 wt % of TEOS RR enhancer works well. Ammonium sulfate performed well in these studies although ammonium acetate and ammonium nitrate should also be considered.

TABLE 7
TEOS RR Enhancer Skew

| | Abrasive | | | | Mo RR | | TEOS RR | | | | | | | | |
|---|---|---|---|---|---|---|---|---|---|---|---|---|---|---|---|
| | grains | | | | enhancer | | enhancer | | | | Removal rate | | Etching rate | | Removal/ |
| | | Conc. | | pH | | Conc. | | Conc. | Oxidizer | | [Å/minute] | | [Å/minute] | | etching |
| Slurry | Type | [wt %] | pH | adjuster | Type | [wt %] | Type | [wt %] | Type | [wt %] | Mo | TEOS | Mo | Stability | rate (Mo) |
| 1 | B | 1.5 | 2.5 | HEDP | A | 0.2 | A | 0.2 | H₂O₂ | 1 | 673 | 324 | 3.4 | Good | 198 |
| 39 | B | 1.5 | 2.5 | HEDP | A | 0.2 | A | 0.05 | H₂O₂ | 1 | 651 | 176 | 3.3 | Good | 197 |
| 40 | B | 1.5 | 2.5 | HEDP | A | 0.2 | A | 0.1 | H₂O₂ | 1 | 651 | 235 | 3.4 | Good | 191 |
| 41 | B | 1.5 | 2.5 | HEDP | A | 0.2 | A | 0.5 | H₂O₂ | 1 | 689 | 366 | 3.8 | Good | 181 |
| 42 | B | 1.5 | 2.5 | HEDP | A | 0.2 | A | 1 | H₂O₂ | 1 | 721 | 394 | 4.2 | Good | 172 |
| 43 | B | 1.5 | 2.5 | HEDP | A | 0.2 | B | 0.2 | H₂O₂ | 1 | 604 | 301 | 3.3 | Good | 183 |
| 44 | B | 1.5 | 2.5 | HEDP | A | 0.2 | C | 0.2 | H₂O₂ | 1 | 633 | 311 | 3.8 | Good | 167 |

In the next study, various oxidizers were investigated (see Table 8). These studies showed that oxidizers having iron ions (Fe ions) exhibited higher Mo etching rates compared to other types of oxidizers, such as hydrogen peroxide.

TABLE 8
Oxidizer Skew

| | Abrasive | | | | Mo RR | | TEOS RR | | |
|---|---|---|---|---|---|---|---|---|---|
| | grains | | | | enhancer | | enhancer | | |
| | | Conc. | | pH | | Conc. | | Conc. | Oxidizer |
| Slurry | Type | [wt %] | pH | adjuster | Type | [wt %] | Type | [wt %] | Type |
| 1 | B | 1.5 | 2.5 | HEDP | A | 0.2 | A | 0.2 | H₂O₂ |
| 45 | B | 1.5 | 2.5 | Phosphoric acid | A | 0.2 | A | 0.2 | KIO₃ |
| 46 | B | 1.5 | 2.5 | Phosphoric acid | A | 0.2 | A | 0.2 | H₅IO₆ |
| 47 | B | 1.5 | 2.4 | Malonic acid | A | 0.2 | A | 0.2 | [Fe(H₂O)₆](NO₃)₂ |
| | | | | | | | | | H₂O₂ |
| 49 | B | 1.5 | 2.5 | Phosphoric acid | A | 0.4 | A | 0.2 | H₅IO₆ |
| 50 | B | 1.5 | 2.4 | Malonic acid | A | 0.4 | A | 0.2 | [Fe(H₂O)₆](NO₃)₂ |
| | | | | | | | | | H₂O₂ |

| | | Removal rate | | Etching rate | | Removal/ |
|---|---|---|---|---|---|---|
| | Oxidizer | [Å/minute] | | [Å/minute] | | etching |
| Slurry | [wt %] | Mo | TEOS | Mo | Stability | rate (Mo) |
| 1 | 1 | 673 | 324 | 3.4 | Good | 198 |
| 45 | 0.2 | 888 | 324 | 8.8 | Good | 101 |
| 46 | 0.2 | 877 | 333 | 8.7 | Good | 101 |
| 47 | 0.01 | 888 | 312 | 9.9 | Good | 90 |
| | 0.5 | | | | | |
| 49 | 0.2 | 899 | 333 | 8.1 | Good | 111 |
| 50 | 0.01 | 890 | 310 | 9.1 | Good | 98 |
| | 0.5 | | | | | |

It will be apparent to those skilled in the art that various modifications and variations can be made in the present invention without departing from the scope or spirit of the invention. Other aspects of the invention will be apparent to those skilled in the art from consideration of the specification and practice of the invention disclosed herein. It is intended that the specification and examples be considered as exemplary only, with a true scope and spirit of the invention being indicated by the following claims.

1. A polishing composition comprising abrasive grains, a molybdenum removal rate enhancer, a TEOS removal rate enhancer, an oxidizer, and water, wherein
the abrasive grains are a sulfonic acid-modified colloidal silica;
the molybdenum removal rate enhancer is a basic amino acid;
the oxidizer is a peroxide; and
wherein the polishing composition has a pH of less than 6.

2. The polishing composition of claim 1, wherein the basic amino acid is selected from the group consisting of arginine, lysine, histidine, and a combination or polymer material thereof.

3. The polishing composition of claim 1, wherein the basic amino acid is arginine.

4. The polishing composition of claim 1, wherein the basic amino acid is present in a concentration ranging from more than 0.01 wt % and less than 1.0 wt %.

5. The polishing composition of claim 1, wherein the TEOS removal rate enhancer comprises an ammonium salt.

6. The polishing composition of claim 1, wherein the TEOS removal rate enhancer is selected from the group consisting of ammonium sulfate, ammonium nitrate, ammonium acetate, ammonium citrate and a combination thereof.

7. The polishing composition of claim 1, wherein the TEOS removal rate enhancer is present in a concentration ranging from 0.05 wt % to 1.0 wt %.

8. The polishing composition of claim 1, wherein the pH of the polishing composition ranges from about 2-5.

9. The polishing composition of claim 1, wherein the basic amino acid has a PI of at least 7.5.

10. The polishing composition of claim 1, wherein the abrasive grains have a mean particle size ranging from 15 nm to 80 nm.

11. The polishing composition of claim 1, wherein the abrasive grains are present in a concentration ranging from 0.5 wt % to 5 wt %.

12. The polishing composition of claim 1, wherein the oxidizer is periodic acid or hydrogen peroxide.

13. The polishing composition of claim 1, wherein the oxidizer is present in a concentration ranging from 0.01 wt. % to 1.5 wt. %.

14. The polishing composition of claim 1, further comprising a pH-adjusting agent.

15. The polishing composition of claim 14, wherein the pH-adjusting agent is selected from the group consisting of HEDP, nitric acid, sulfonic acid, acetic acid, phosphoric acid, phosphonic acid, and 2-hydroxyisobutyric acid.

16. A polishing composition comprising abrasive grains, a molybdenum removal rate enhancer, a TEOS removal rate enhancer, an oxidizer, and water,
wherein a ratio of molybdenum removal rate (Å/minute) to molybdenum etching rate (Å/minute) is at least 50.

17. A method for polishing a substrate, the method comprising the steps of: (a) providing the polishing composition of claim 1; (b) providing a substrate, wherein the substrate comprises a molybdenum-containing layer; and (c) polishing the substrate with the polishing composition to provide a polished substrate.

18. The method of claim 17, wherein in the method, a ratio of molybdenum removal rate to molybdenum etching rate is at least 50.

19. The method of claim 17, wherein the substrate further comprises a TEOS layer.
